(19) United States
(12) Patent Application Publication
(10) Pub. No.: US 2015/0288146 A1
(43) Pub. Date: Oct. 8, 2015

(54) VERTICAL CAVITY SURFACE EMITTING LASERS WITH SILICON-ON-INSULATOR HIGH CONTRAST GRATING

(71) Applicant: The Regents Of The University Of California, Oakland, CA (US)

(72) Inventors: Connie Chang-Hasnain, Palo Alto, CA (US); Christopher Chase, Kensington, CA (US); Yi Rao, Albany, CA (US)

(73) Assignee: THE REGENTS OF THE UNIVERSITY OF CALIFORNIA, Oakland, CA (US)

(21) Appl. No.: 14/055,058

(22) Filed: Oct. 16, 2013

Related U.S. Application Data
(63) Continuation of application No. PCT/US2012/035697, filed on Apr. 28, 2012.
(60) Provisional application No. 61/480,471, filed on Apr. 29, 2011.

(51) Int. Cl. H01S 5/183; H01S 5/40; H01S 5/20; H01S 5/187; H01S 5/02

(52) U.S. Cl. CPC H01S 5/18386; H01S 5/187; H01S 5/021; H01S 5/0215; H01S 5/2063; H01S 5/4025

(57) ABSTRACT

A surface emitting laser apparatus is formed using a patterned silicon-on-insulator (SOI)-like substrate which is patterned with a buried sub-wavelength high contrast grating and adapted for bonding of a half-VCSEL device containing at least an active region and an upper mirror, to create a VCSEL. The wavelength of the VCSEL, or any individual VCSEL within an array of VCSEL devices, can be set in response to changing HCG characteristics of the lower mirror in the SOI-like substrate, or in the region above the lower mirror within the half-VCSEL. The inventive VCSEL device and fabrication method are beneficial for a number of application and devices.

### CROSS-REFERENCE TO RELATED APPLICATIONS

This application is a 35 U.S.C. §111(a) continuation of PCT international application number PCT/US2012/035697 filed on Apr. 28, 2012, incorporated herein by reference in its entirety, which is a nonprovisional of U.S. provisional patent application Ser. No. 61/480,471 filed on Apr. 29, 2011, incorporated herein by reference in its entirety. Priority is claimed to each of the foregoing applications.

The above-referenced PCT international application was published as PCT International Publication No. WO 2012/149497 on Nov. 1, 2012 and republished on Mar. 21, 2013, which publications are incorporated herein by reference in their entireties.

### STATEMENT REGARDING FEDERALLY SPONSORED RESEARCH OR DEVELOPMENT

This invention was made with Government support under Grant Number N00244-09-1-013 awarded by the Department of Defense (DOD) under the National Security Science and Engineering Faculty Fellowship (NSSEFF) Program, and under Grant No. EEC-0812072 awarded by the National Science Foundation (NSF) Center for Integrated Access Networks (CIAN). The Government has certain rights in the invention.

### INCORPORATION-BY-REFERENCE OF MATERIAL SUBMITTED ON A COMPACT DISC

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to integrated circuit lasers, and more particularly to vertical cavity surface emitting lasers with silicon-on-insulator (SOI) sub-wavelength high-contrast gratings (HCG).

2. Description of Related Art

Vertical cavity surface emitting lasers (VCSELs) are a promising low cost laser source for use in a wide range of applications, such as within metro area access networks, passive optical network (PON) applications, active optical cables and other datacom links, as well as a source for silicon photonics applications. In particular, VCSELs emitting in the 1.3 μm to about 1.6 μm wavelength range are of interest for long-reach or wavelength-division-multiplexed optical interconnects.

In many applications, it is desirable to have arrays of VCSEL devices operating at multiple wavelengths, specifically in which individual VCSELs in the array operate at different wavelengths. To reduce manufacturing costs these devices need to be fabricated on the same integrated circuit (chip), such as for use within wavelength division multiplexed (WDM) systems.

However, many problems arise when trying to fabricate VCSELs having a span of wavelengths on a single chip. In particular, many problems arise in attempting to modify the processing of each chip to alter its wavelength while controlling other device characteristics to maintain matching.

Accordingly, the present invention allows lasers with individual wavelengths to be more readily fabricated, and overcomes other shortcomings of previous surface-emitting laser designs.

### BRIEF SUMMARY OF THE INVENTION

The present invention provides apparatus and methods for fabricating surface-emitting laser devices, and more particularly surface-emitting laser devices within an array of surface-emitting laser devices in an integrated circuit, in which the wavelengths of the individual surface-emitting laser devices can be individually selected. There are a number of benefits to providing arrays of devices operating at multiple wavelengths on the same chip to support low cost manufacturing of wavelength division multiplexed (WDM) systems. By engineering the wavelength in the cavity either by varying the reflectivity phase of the High Contrast Grating (HCG) or varying the depth of the air gap between the HCG and rest of the structure, changing the total optical path length, an array of surface-emitting lasers can be attained at different wavelengths.

One preferred surface emitting laser is the vertical cavity surface-emitting laser (VCSEL). The following embodiments describe the use of a VCSEL, although the elements of the apparatus and method are also applicable to other surface-emitting laser types.

The present invention describes a novel VCSEL apparatus and fabrication method in which the HCG lower mirror is formed on a silicon-on-insulator (SOI) wafer and integrated with VCSELs, thus enabling large-scale manufacturing. In addition, the methods are applicable to realizing multiwavelength VCSEL arrays and integration with an in-plane waveguide.

An embodiment of the present invention uses a sub-wavelength high contrast grating (HCG) fabricated on SOI as a bottom mirror, and a monolithic compound material based HCG or DBR as a top mirror on an InP-based VCSEL, which is exemplified as emitting at 1.55 μm, although this can be applied to obtain any wavelength between 0.1 μm and about 10 μm grown on InP, GaAs, GaSb, GaN, GaP or sapphire substrates. This method allows for easy integration with other Si-based optical devices. In particular, a coupler can be formed on the SOI wafer allowing for a simple method to couple the array of VCSELs into a single or multiple optical fibers, and/or other optical devices such as optical ports, filters, multiplexers, demultiplexers, and photodetectors. This could also be used as a light source for Si-photonics based optical circuits. This VCSEL approach has great potential to reach a lower manufacturing cost than other long wavelength WDM VCSEL approaches.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a schematic of an SOI HCG VCSEL according to an embodiment of the present invention, showing a DBR top mirror, and an Si HCG bottom mirror whose geometry can be altered to change VCSEL wavelength.

FIG. 2 is a schematic of an SOI HCG VCSEL according to an embodiment of the present invention, showing epitaxial HCG top mirror and an Si HCG bottom mirror whose geometry can be altered to change VCSEL wavelength.

FIG. 3 is a schematic of an SOI HCG VCSEL according to an embodiment of the present invention, showing an Si HCG bottom mirror, DBR top mirror, and sacrificial layers which can be etched to change operating wavelength.

FIG. 4 is a schematic of an SOI HCG VCSEL with metal-based bonding according to an embodiment of the present invention, showing Si HCG bottom mirror, epitaxial HCG top mirror, and sacrificial layers which can be etched to change operating wavelength.

FIG. 5 is a schematic of an SOI HCG VCSEL with metal-based bonding according to an embodiment of the present invention, showing etching of sacrificial regions for defining operating wavelength.

FIG. 6A is a graph showing fabrication tolerance in duty cycle and period for a TM SOI HCG VCSEL configuration according to a TM embodiment of the present invention.

FIG. 6B is a graph showing high reflectivity bandwidth of HCG utilizing in a TM SOI HCG VCSEL according to a TM embodiment of the present invention, with an inset showing HCG segment geometry variables.

FIG. 7A is a graph showing fabrication tolerance in duty cycle and period for a TE SOI HCG VCSEL configuration according to a TE embodiment of the present invention.

FIG. 7B is a graph showing high reflectivity bandwidth of HCG utilizing in a TE SOI HCG VCSEL according to a TE embodiment of the present invention, with an inset showing HCG segment geometry variables.

FIG. 8A is a graph showing pulse characterization with an LI curve under pulsed operation, found according to an embodiment of the present invention.

FIG. 8B is a graph showing pulse characterization with a spectrum of pulsed and CW operation, found according to an embodiment of the present invention.

FIG. 9 is a schematic of an SOI HCG VCSEL with chirped HCG Lens according to an embodiment of the present invention.

FIG. 10 is a schematic of an SOI HCG VCSEL with HCG vertical coupler according to an embodiment of the present invention.

FIG. 11 is a schematic of a multi-wavelength HCG VCSEL array providing different phase response by varying HCG dimension according to an embodiment of the present invention.

FIG. 12 is a schematic of a multi-wavelength HCG VCSEL array fabricated with varying cavity length according to an embodiment of the present invention.

### DETAILED DESCRIPTION OF THE INVENTION

The present invention pertains to integrated circuit laser structures which incorporate a high-contrast grating in a manner that allows for readily adapting device parameters, in particular wavelength, based on simple lithography changes and without the need to alter process steps or times from one laser device to another within an integrated laser array. By way of example, and not of limitation, embodiments of the present invention comprise a half-laser laser structure fabricated over, or bonded onto, a HCG pre-patterned silicon-on-insulator (SOI) substrate.

In the following embodiments the laser utilized is a vertical cavity surface emitting laser (VCSEL), although it will be appreciated that the present invention can be utilized with other types of surface emitting lasers.

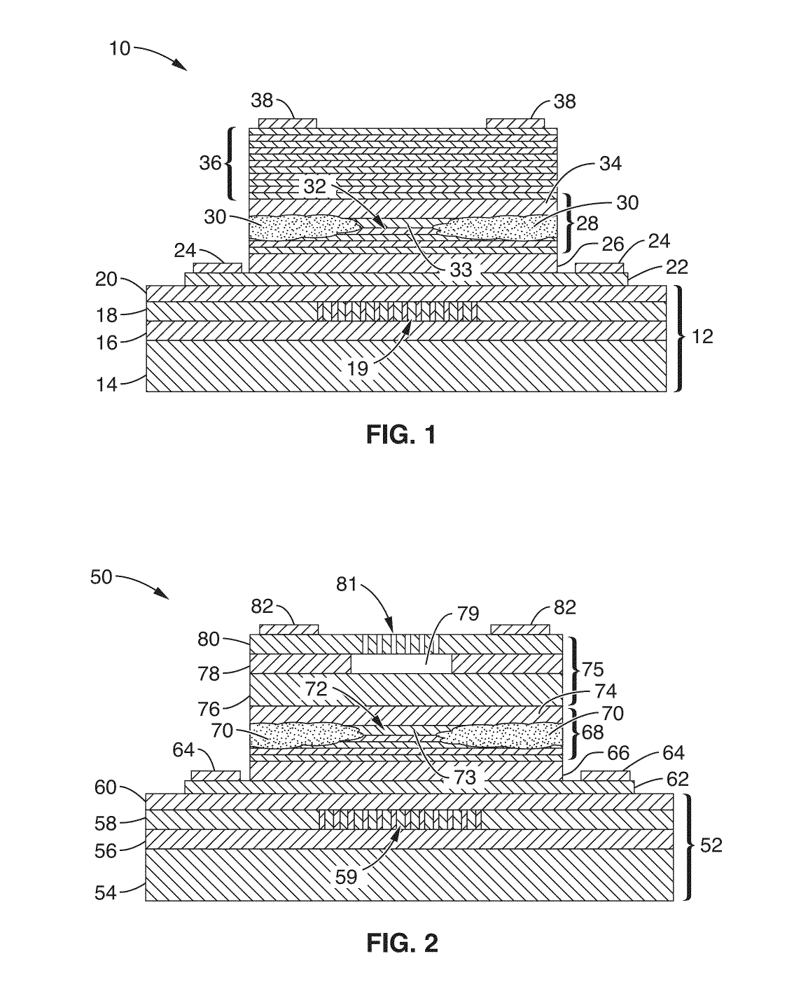

FIG. 1 illustrates an embodiment 10 of a silicon on insulator (SOI) form of high contrast grating (HCG) VCSEL, showing a specially adapted SOI substrate 12 upon which the remainder of the VCSEL is fabricated. It should be appreciated that silicon on insulator (SOI) technology is known to refer to the use of a layered silicon-insulator-silicon substrate in place of conventional silicon substrates in semiconductor manufacturing. A typical SOI substrate contains a layer of silicon dioxide at a predetermined depth within a silicon wafer. An SOI-based device differs from conventional silicon-based devices in that the silicon layer is above an electrical insulator, typically silicon dioxide, or sapphire in the case of the similar silicon on sapphire (SOS) substrates. The inclusion of the buried insulator layer provides a necessary cladding, so as to prevent light leakage to the silicon layer. Selection of insulator type depends largely on intended application and cost factors, with silicon dioxide being probably the least costly of these buried insulator layer substrates. SOI wafers have achieved widespread use in the industry.

In an embodiment of the present invention, SOI is configured specifically for supporting the VCSEL device by inclusion of a buried HCG reflector within the substrate. Instead of simply having a buried insulator layer, the inventive patterned substrate 12 comprises a silicon base layer 14 (e.g., remainder of the wafer), a lower spacer layer 16 (oxide spacer), a grating layer 18 with periodic spaced apart segments 19 of Si, and an upper spacer layer 20 (oxide spacer). In this general configuration, the grating layer comprises Si, but is not a solid layer of Si as in an SOI. Instead, and according to the invention herein, the Si is patterned with grating segments as a series of parallel bars whose geometry is defined in thickness, width, spacing, period and duty cycle, and spacing in regard to adjacent layers control its reflectivity characteristics.

The material of the HCG grating, Si in this case, has a refractive index which significantly differs from the layers above and below it on the HCG patterned SOI wafer. In this example, the HCG grating segments have a high refractive index, while the surrounding regions have a low refractive index. The difference in refractive index between the high and low index materials is preferably greater than one unit, and more preferably exceeds two. It will be noted that SiO₂ has a refractive index of about one and a half, while crystalline Si has a refractive index exceeding three.

Referring again to FIG. 1, the remaining portions of the VCSEL are fabricated over this HCG patterned “SOI-like” substrate 12 which acts as the bottom mirror. Over the substrate, and its integrated HCG bottom mirror 19, the laser cavity with an active region is formed, and the top mirror through which the laser light is output is formed above the laser cavity.

More particularly, in this embodiment there is a contact layer 22 above the substrate, upon which a bottom contact 24 is shown. A current spreading layer 26 creates a current spreading path above the contact layer 22. An active portion 28 contains the active region and is also preferably configured for current confinement. The active portion 28 can incorporate optional DBR layers to extend the current spreading path. The active portion 28 optionally includes a current aperture 32 within which the lasing occurs. The current aperture 32 is formed, for example, by implanting hydrogen ions (H+) in regions 30. The active portion 28 may also contain a tunnel junction (not shown) between the current spreading layer 26 and the active region. The active portion 28 also contains a current confinement layer 33 and the active region itself 34. The active region typically contains quantum structures (e.g., quantum well, quantum wires, and so forth), but may be active in response to other material, such as bulk material. Above the active region is the top mirror structure 36, which in this embodiment is shown as comprising a series of distributed Bragg reflector (DBR) layers. The DBR comprises alternate high and low index materials, and more preferably comprises either epitaxial (compound semiconductor) or dielectric (SiO₂/SiN/CaF₂, etc.). A top contact 38 is shown which preferably surrounds the optical output area of the device.

FIG. 2 illustrates a similar SOI HCG VCSEL embodiment 50, which utilizes an HCG for a top mirror instead of the DBR layers. A specially adapted SOI substrate 52 is shown as comprising a base layer 54 (e.g., Si), a lower spacer layer 56 (e.g., SiO₂), a grating layer 58 (e.g., grating patterned Si) with periodic spaced apart segments 59 of Si, and an upper spacer layer 60. The top half of the VCSEL (above the SOI-like HCG patterned substrate) contains the contact and current spreading layers, the active region, and the top mirror. A contact layer 62 is provided upon which a contact 64 is formed. A current spreading layer 66 is provided for creating a current spreading path above contact layer 62. An active portion 68 contains the active region 74 and is also preferably configured for current confinement. The active portion 68 can incorporate optional DBR layers to extend the current spreading path. An optional tunnel junction (not shown) can be formed within active portion 68. Optionally within the active portion there is a current aperture 72 within which the lasing occurs. The current aperture 72 is formed, for example, by implanting hydrogen ions (H+) in regions 70. The active portion 68 also contains a current confinement layer 73 and the active region itself 74. The active region typically contains quantum structures (e.g., quantum well, quantum wires, and so forth), but may be active in response to other material such as bulk material. Above the active region there is a top mirror structure 75, shown with a current spreading layer 76, a sacrificial layer 78 with an air gap 79, and an upper grating layer 80 with an HCG grating 81 comprising HCG grating segments disposed over the cavity of the laser. A top contact 82 is provided which preferably surrounds the optical output area of the device.

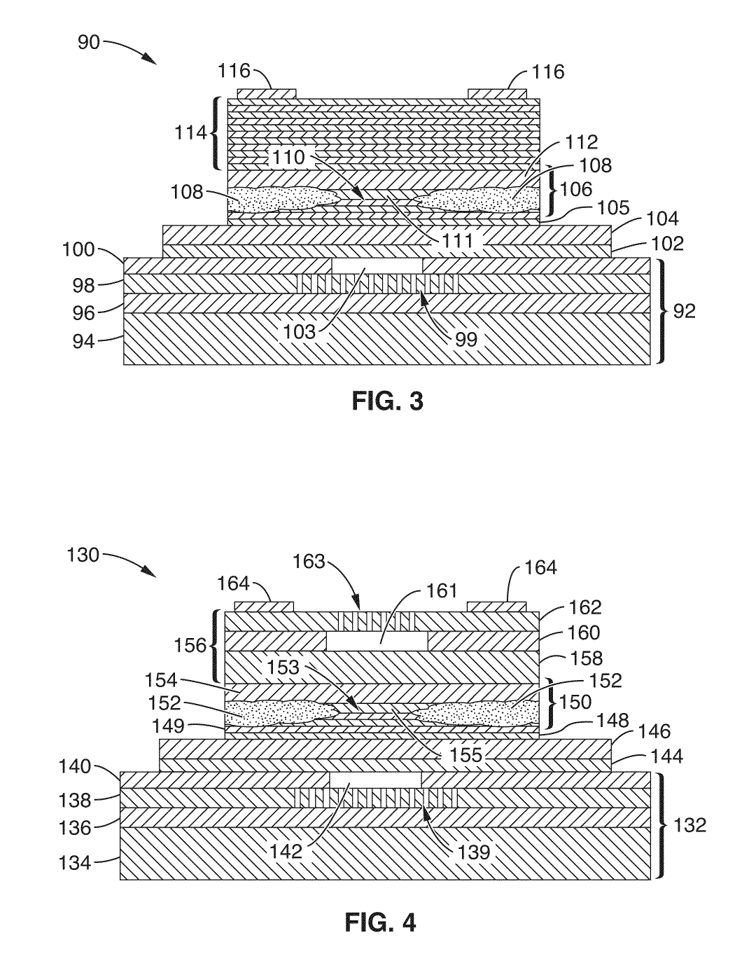

FIG. 3 and FIG. 4 show variations of the lower HCG mirror based VCSEL shown in FIG. 1 and FIG. 2, such as by replacing the upper spacer layer with a metallization spacer layer which is patterned above the lower HCG reflector.

The example embodiment 90 of FIG. 3 shows an HCG patterned substrate 92 comprising a silicon base layer 94 (e.g., remainder of the wafer), a lower spacer layer 96 (e.g., SiO₂ oxide spacer), and a grating layer 98 (e.g., patterned Si) with periodic spaced apart segments 99 of Si (with air or SiO₂ between grating segments), upon which is a patterned metal layer 100 having an air spacer 103 (e.g., metal etched or lifted-off). This metal layer replaces the need for bottom contacts 24 and 64 shown in FIG. 1 and FIG. 2, respectively. It will be noted that the HCG patterned substrate may be fabricated with the metal layer or patterned metal layer, or this metallization and patterning step can be later performed to an HCG patterned SOI substrate prior to adding the half-VCSEL structure, or forming its layers thereupon.

The top half of the VCSEL (above the SOI-like HCG patterned substrate) contains the contact and current spreading layers, the active region, and the top mirror. Upon substrate 92 is a contact layer 102 and current confinement/sacrificial layer 104. A contact layer 102 is shown upon which contacts can be formed. A current spreading layer 104 can also be a sacrificial layer for extending spacer 103. Optional DBR layers 105 are shown for extending the current spreading path. An active portion 106 contains the active region 112 and is also preferably configured for current confinement. Active portion 106 can also incorporate an optional tunnel junction (not shown). Active portion 106 is shown with optional current aperture 110 within which the lasing occurs. Current aperture 110 is formed, for example, by implanting hydrogen ions (H+) in regions 108. The active portion 106 also contains a current confinement layer 111. It should be noted that implementation is not limited to active regions containing quantum structures. Above the active region is the top mirror structure 114, which in this embodiment is shown as comprising a series of distributed Bragg reflector (DBR) layers. A top contact 116 is shown which preferably surrounds the optical output area of the device.

The example embodiment 130 of FIG. 4 shows an HCG patterned substrate 132 comprising a silicon base layer 134 (e.g., remainder of the wafer), a lower spacer layer 136 (e.g., SiO₂ oxide spacer), and a grating layer 138 (e.g., patterned Si) with periodic spaced apart segments 139 of Si (with air or SiO₂ between grating segments), upon which is a patterned metal layer 140 having an air spacer 142 (e.g., metal etched away). This metal layer replaces the need for bottom contacts 24 and 64 shown in FIG. 1 and FIG. 2, respectively. It will be noted that the HCG patterned substrate may be fabricated with the metal layer, or patterned metal layer, or this metallization and patterning step can be later performed to an HCG patterned SOI substrate prior to adding the half-VCSEL structure, or forming its layers thereupon. The top half of the VCSEL (above the SOI-like HCG patterned substrate) contains the contact and current spreading layers, the active region and top mirror. A contact layer 144 is shown which is the contact, or upon which contacts are formed. A current spreading layer 146 can also provide a sacrificial layer extension of air spacer 142. Optional additional DBR layers 148 are seen adjacent an active portion 150. Active portion 150 contains active region 154 and is also preferably configured for current confinement. Active portion 150 can incorporate an optional tunnel junction (not shown). An optional current aperture 153 is shown with the active portion within which the lasing occurs. Current aperture 153 is formed, for example, by implanting hydrogen ions (H+) in regions 152. The active portion 150 also contains a current confinement layer 155, and the active region itself 154. Above the active region is the top mirror structure 156, with current spreading layer 158, sacrificial layer 160 with cavity 161, and upper grating layer 162 with an HCG grating 163 comprising HCG grating segments disposed over the cavity of the laser. A top contact 164 is shown which preferably surrounds the optical output area of the device.

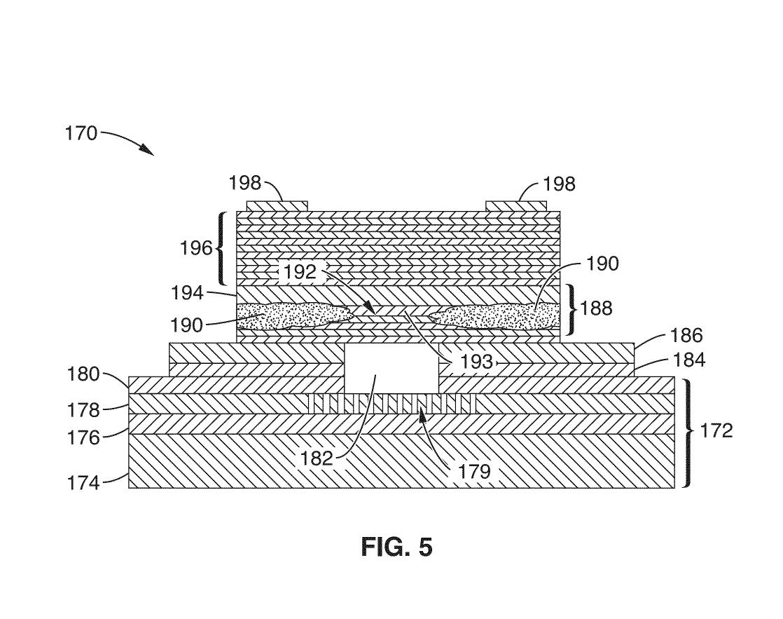

FIG. 5 illustrates an example of an HCG patterned SOI-like substrate similar to FIG. 3 wherein the spacer (103 of FIG. 3) is etched to a desired depth in/through the contact layer and sacrificial layer creating an air spacer for the bottom HCG in response to etching into sacrificial layer. It should be appreciated that this method provides for more flexible and accurate depth control, while improving the reflectivity of the bottom mirror. The example embodiment 170 of FIG. 5 has an HCG patterned substrate 172 with a silicon base layer 174 (e.g., remainder of the wafer), a lower spacer layer 176 (e.g., SiO₂ oxide spacer), and a grating layer 178 (e.g., patterned Si) with periodic spaced apart segments 179 of Si (with air or SiO₂ between grating segments), upon which is a patterned metal layer 180 having an air spacer 182 in which a portion of the metal is etched and lifted-off.

The top half of the VCSEL (above the SOI-like HCG patterned substrate) contains the contact and current spreading layers, the active region and top mirror. A contact layer 184 is shown for making contact with substrate 172. A current spreading layer 186 can also provide a sacrificial layer through which, along with contact layer 184, the air spacer 182 can be extended to a desired depth. It should be noted that the etching of this air gap is directed at selecting different longitudinal modes of the laser. The method provides improved control of cavity depth and improves the reflectivity of the bottom mirror.

Active portion 188 contains active region 194 and is also preferably configured for current confinement. Active portion 180 can incorporate optional DBR layers to extend the current spreading path as desired. An optional tunnel junction (not shown) can be included in the active portion. The active portion can include a current aperture 192 within which the lasing occurs. Current aperture 192 is formed, for example, by implanting hydrogen ions (H+) in regions 190. The active portion 188 also contains a current confinement layer 193, as well as the active region itself 194. Above the active region is a DBR top mirror structure 196, although the HCG top mirror structure of FIG. 4 may be equally substituted. A top contact 198 is shown that operates in combination with bottom contact 180 in providing device power.

The present invention is described for use with both TM and TE designs. In a TM design, the polarization of the electrical field is perpendicular to the HCG and the HCG is configured (designed) to have a high reflectivity for this polarization. In a TE design, the polarization of the electrical field is parallel to the HCG, and the HCG is configured (designed) to have a high reflectivity for this polarization. In general, the TM designs have better fabrication tolerance compared with TE designs. It will also be noted that TM and TE designs typically require different device thicknesses which provide flexibility in choosing SOI substrates.

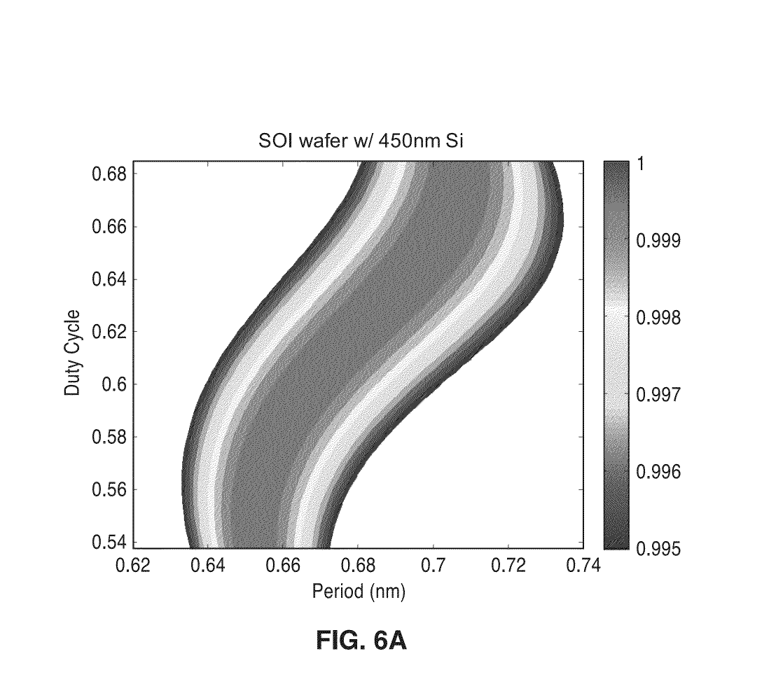

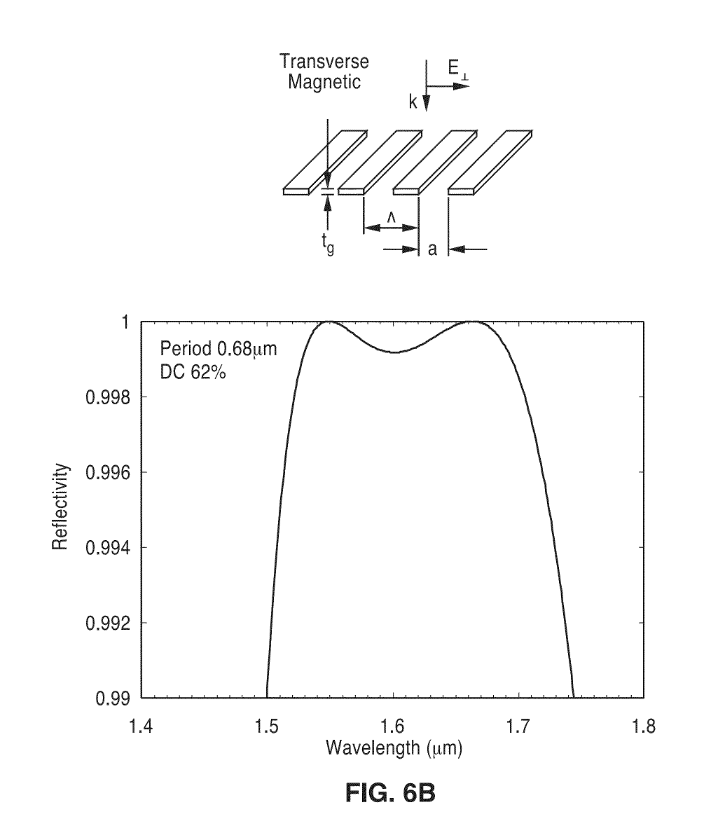

FIGS. 6A and 6B illustrate manufacturing tolerances for the transverse magnetic (TM) design of FIG. 1 and FIG. 2. In FIG. 6A fabrication tolerance is illustrated, with a grating duty cycle tolerance larger than 10%, and the tolerance to period variation is larger than 5%. FIG. 6B illustrates that a bandwidth providing more than 99% reflectivity can be as wide as 250 nm with given silicon layer thickness as 450 nm.

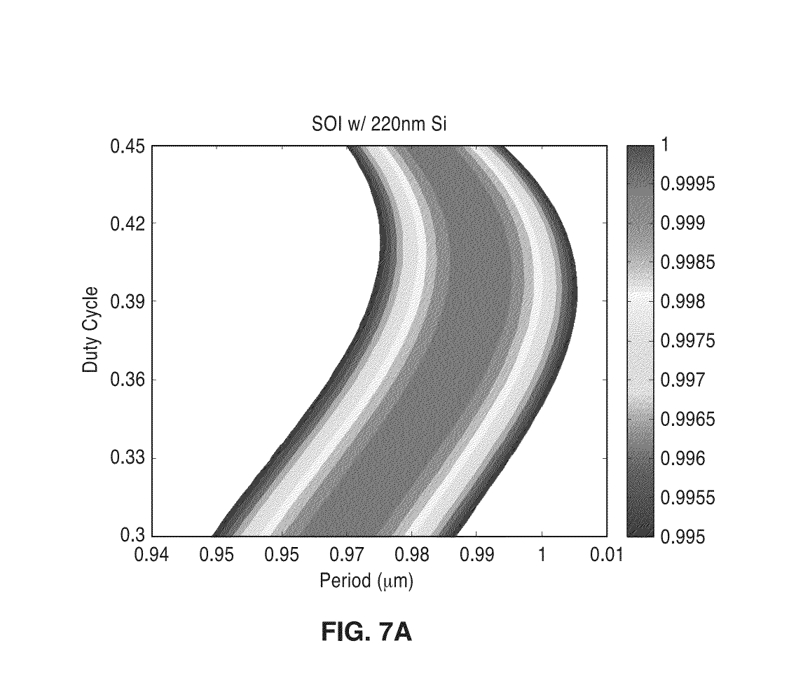

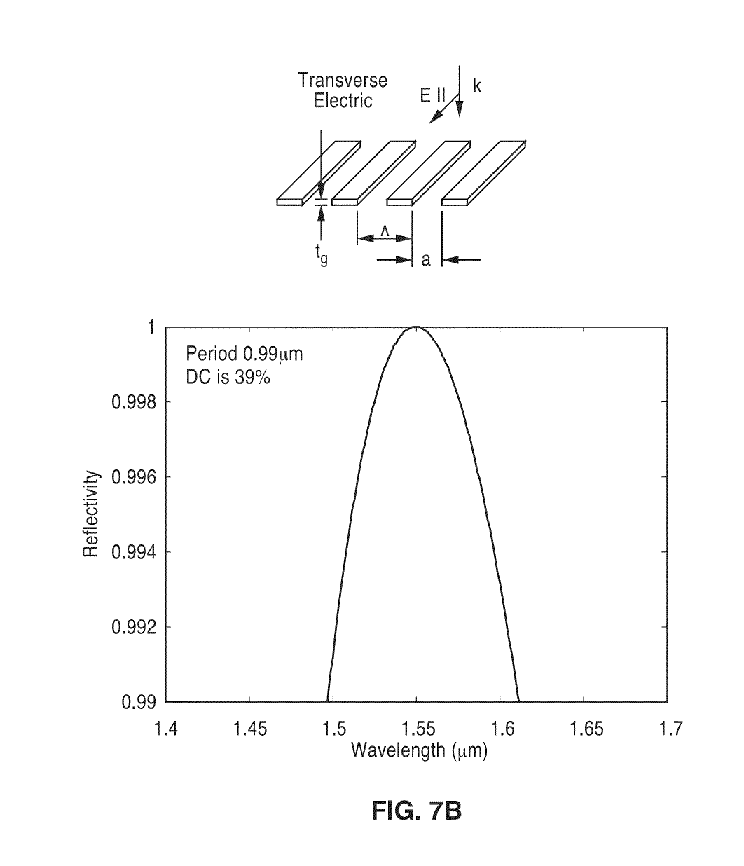

FIGS. 7A and 7B illustrate manufacturing tolerances for the transverse magnetic (TE) design of FIG. 3 and FIG. 4. In FIG. 7A, fabrication tolerance results are shown for a transverse electric (TE) design of the HCG mirror, with 10% and 5% fabrication tolerance in duty cycle and period respectively. From FIG. 7B it can be seen that the bandwidth tolerance provides greater than 99% reflectivity across a band larger than 100 nm. It should be appreciated that the examples described are only samples, and that the HCG layer could span a wide range of thicknesses from tens of nm to thousands of nm (μm).

It should be noted that the low index material surrounding the HCG is preferably thick enough so that evanescent waves from the HCG do not couple into high index materials far from the HCG. Usually a distance equal to a quarter of the wavelength of interest is sufficient to meet this requirement. In summary, SOI HCG reflectivity and bandwidth is high enough to be a VCSEL mirror, and the fabrication of Si HCG can leverage on mature CMOS manufacturing techniques.

In one example implementation of the above embodiments, the half VCSEL structure (above the HCG patterned SOI like substrate) is aligned and bonded onto the SOI substrate, where a spacer, such as air/polymer/oxide, can be used to maintain high contrast between the HCG and the remainder of the VCSEL structure. A metal contact is defined after III-V substrate removal, and finally the individual VCSEL devices on the substrate are electrically isolated from each other by wet/dry etching.

Different bonding technologies can be utilized for connecting the half-VCSEL to the HCG patterned SOI-like substrate, including oxide-to-oxide or oxide-to-semiconductor bonding (as seen in FIG. 1 and FIG. 2), or thermal compressed or eutectic metal bonding (as seen in FIG. 3 and FIG. 4). In both cases, the bottom mirror is an HCG, preferably an Si-based HCG, and the top mirror can be epitaxial DBR, HCG or dielectric DBR. In the case of a top mirror formed by HCG or dielectric DBR, the air spacer (e.g., 79 in FIG. 2) could be defined by the thickness of metal or extra etching into sacrificial layer.

It should be appreciated that oxide-to-oxide or oxide-to-semiconductor bonding is generally considered to have improved controllability of the spacer thickness than thermal compressed or eutectic metal bonding, while it also replaces an air spacer with an oxide spacer that is more robust. It will be noted that utilization of the oxide spacer (e.g., SiO₂) aids thermal response since the thermal conductivity of SiO₂ is higher than air. In addition, the structure is more stable because there is no air pocket. However, this bonding technique requires relative high temperature/pressure for bonding, and requires pre-planarization prior to the bonding step. Metal bonding has improved thermal conductivity, resistivity and less need of planarization. Thermal compressed metal bonding requires relatively high bonding temperature and pressure, while eutectic metal bonding can lower the requirement of bonding temperature/pressure.

The HCG grating VCSEL embodiments shown in FIG. 1 through FIG. 5, utilize by way of example and not limitation, a bonded Si high contrast grating (HCG) as a bottom mirror, and a monolithic compound material based HCG or DBR as a top mirror on an InP-based VCSEL emitting at 1.55 μm. It should be appreciated, however, that the geometry of these devices can be designed to generate any desired wavelength between 0.1 μm and 10 μm, fabricated on any of a number of substrate materials including InP, GaAs, GaSb, GaN, and GaP substrates, which allows for easy integration with other Si-based optical devices. In particular, a coupler could also be fabricated on the SOI wafer allowing for a simple method to couple the array of VCSELs into a single optical fiber. This could also be utilized as a light source for Si-photonics based optical circuits. This VCSEL approach has great potential to decrease manufacturing cost over the use of other long wavelength WDM VCSEL approaches.

The half-VCSEL laser structure, bonded on top of the HCG pre-patterned SOI substrates, can be fabricated of group III-V or II-VI compounds, including InP-, GaAs-, GaSb-, GaN-, GaP-, ZnSSe-, ZnCdS-, ZnO2-, based compound semiconductor materials and combination thereof. The half VCSEL heterostructure comprises a current spreading layer, active (light emitting) region and top mirror.

Between the current spreading layer and the active region, an optional aperture can be formed (e.g., by means of H+ implantation) to facilitate efficient carrier confinement and reduced loss. The active region may comprise quantum well, quantum wire, quantum dot or even bulk regions. Emission wavelength of the active region can range from 0.1 μm to 10 μm, and top mirror could be epitaxial DBR, dielectric DBR or HCG mirror. The SOI substrate comprises Si substrate, an oxide spacer, and a Si device layer. The oxide space and Si layer thicknesses require design, but can be in the range of 0.01 to about 10 times the free-space wavelength. An HCG structure on SOI substrate is preferably patterned by lithography, and then formed by standard etching technique. The HCG can be configured with a uniform grating, or chirped grating with reflection lensing effect. The HCG can be configured with high reflection back to half-VCSEL, or to couple part of the light in a Si-waveguide underneath the half-VCSEL to convert the output light to in-plane, such as for directing it to optical output ports, structures, or receiving devices.

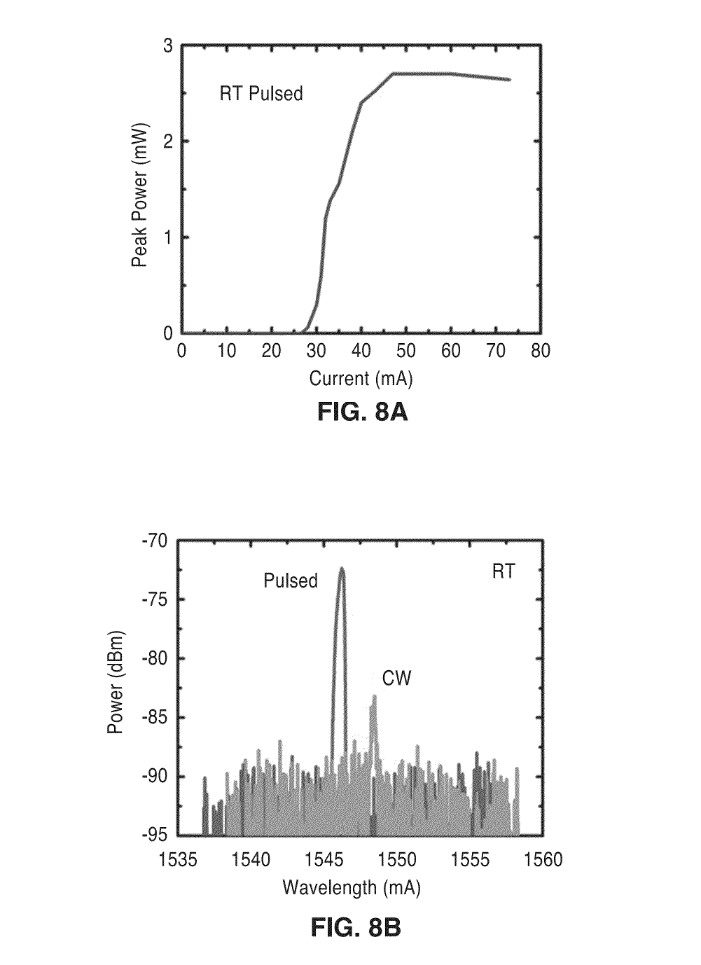

FIG. 8A and FIG. 8B depict pulsed characteristics for the device of FIG. 5, showing that pulsed operation has been achieved having a peak output power of 2.7 mW with 26 kA/cm2 threshold current density (FIG. 8A). The laser is emitting at 1545 nm under pulsed operation, and the peak power of cavity mode is 7 dB high than noise floor with continuous wave (CW) operation, as seen in FIG. 8B. In addition, the thermal conductivity is as good as 0.7 K/mW. By optimizing the process it appears that room temperature continuous wave (CW) operation is achievable.

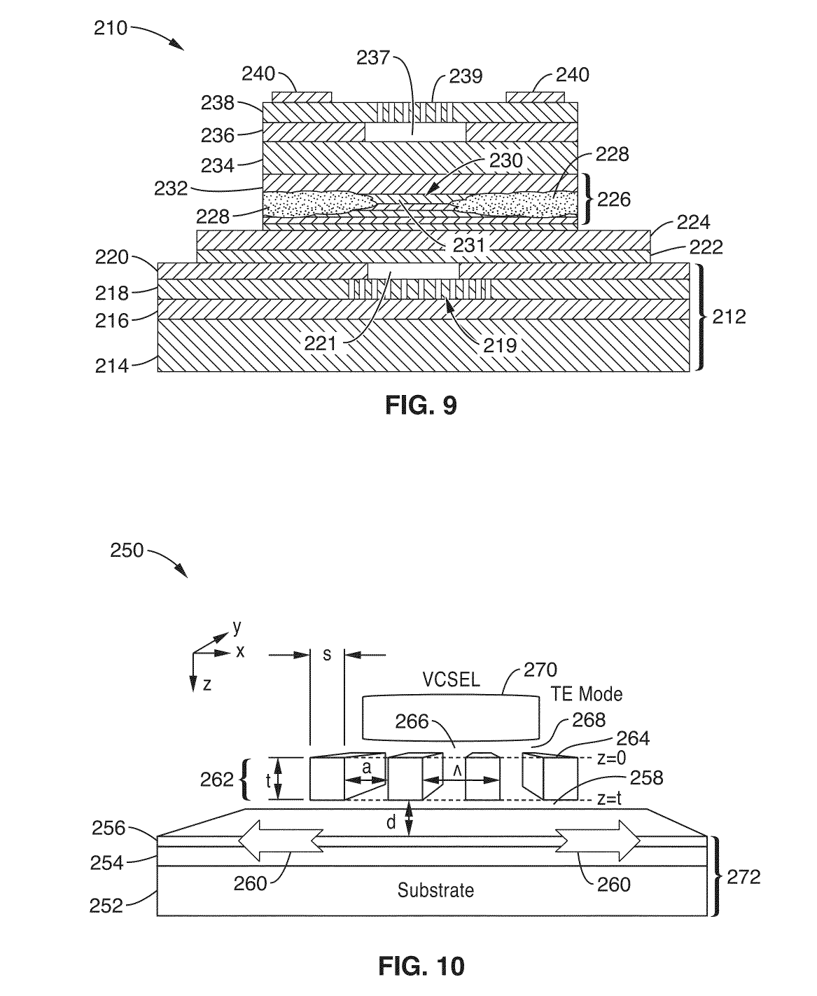

FIG. 9 illustrates an example embodiment 210 of an HCG patterned substrate VCSEL having an upper HCG mirror utilizing HCG lensing to provide extra optical mode confinement, and thus lower threshold and higher efficiency.

A chirped HCG lens is seen on an SOI HCG VCSEL in FIG. 9, which is otherwise like the VCSEL seen in FIG. 4. Example embodiment 210 shows a HCG patterned substrate 212 having a silicon base layer 214, a lower spacer layer 216, a grating layer 218 with periodic spaced apart segments 219 of Si, upon which is a patterned metal layer 220 having an air spacer 221 which can optionally extend into any desired portion of contact and sacrificial layers above.

The top half-VCSEL is shown with a contact layer 222 for contacting substrate 212. A current spreading layer 224, is also a sacrificial layer, through which air spacer 221 can be extended through contact layer 222 and current spreading/sacrificial layer 224. It should be noted that the etching of this air gap selects different longitudinal modes of the laser.

In this embodiment, the active portion 226 contains an active region 232 and is also preferably configured for current confinement. Active portion 226 can incorporate optional DBR layers to extend current spreading path as desired. An optional tunnel junction (not shown) can be included in the active portion. The active portion can include an optional current aperture 230 within which the lasing occurs. Current aperture 230 is formed, by way of example, by implanting hydrogen ions (H+) in regions 228, thus restricting the extent of device operation to current aperture 230. The active portion 226 also contains a current confinement layer 231, as well as the active region itself 232. Above the active region 232 is a current spreading layer 234, which may contain optional additional DBR layers (not shown), A sacrificial layer 236 is seen with spacer 237. It will be noted that spacer 237 can optionally extend into current spreading layer 234 in similar manner as spacer 221. Over the sacrificial layer is an upper grating layer 238 with an HCG grating 239 having chirped (varying period) HCG grating segments over the laser cavity. A top contact 240 is shown which preferably surrounds the optical output area of the device.

FIG. 10 illustrates an example embodiment 250 of a configuration in which the vertical output light from the SOI HCG VCSEL of any these embodiments is being coupled into an in-plane horizontal waveguide or other silicon photonics components by an HCG interoperably connected to a waveguide by vertical coupler. Thus, the optical coupler shown can be integrated with the laser array embodiments described herein for combining laser outputs. These laser outputs can be directed to other optical devices, such as filters, multiplexers, demultiplexers, photodetectors or other known optical elements, or to an optical port, such as connecting to an optical fiber or other optical communication path for conveying signals outside the device. In this embodiment, waveguide 272 is shown comprising a substrate layer 252, spacer layer 254, and waveguide (core) layer 256. Coupled through gap 258, which has spacing (d), is a high contrast grating 262 having segments 264 with width (s) and thickness (t), and inter-segment spaces 266 with width (a), the combination providing period (Λ). The top of the grating is considered to be z=0 position, with the lower end of the grating at z=t. In operation, light is emitted from VCSEL 270 to HCG 262 over operable gap 266, wherein the HCG transfers the optical energy through gap 258 symmetrically in opposing directions 260 in waveguide layer 254 of waveguide 272.

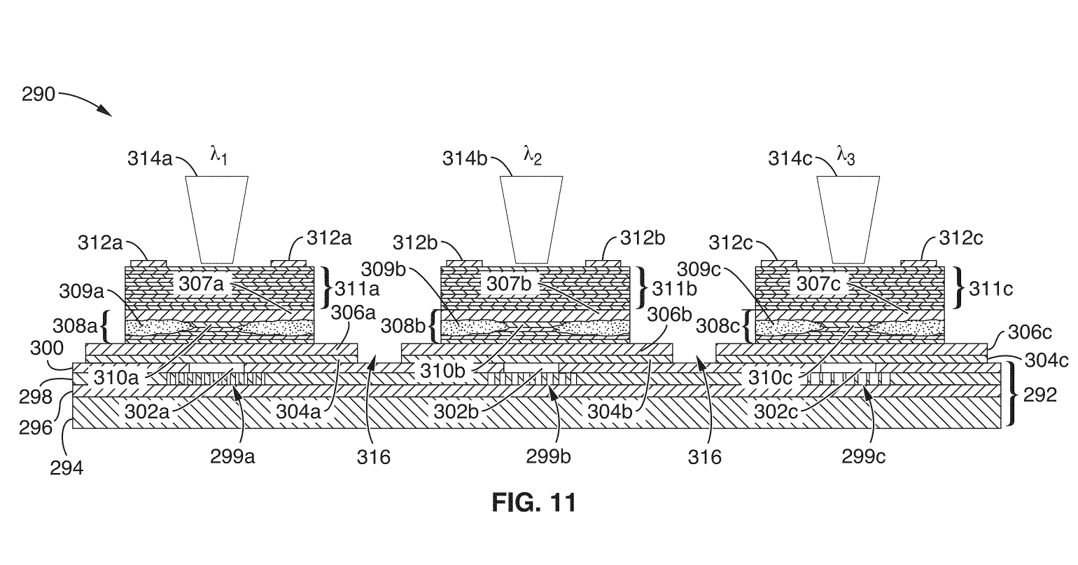

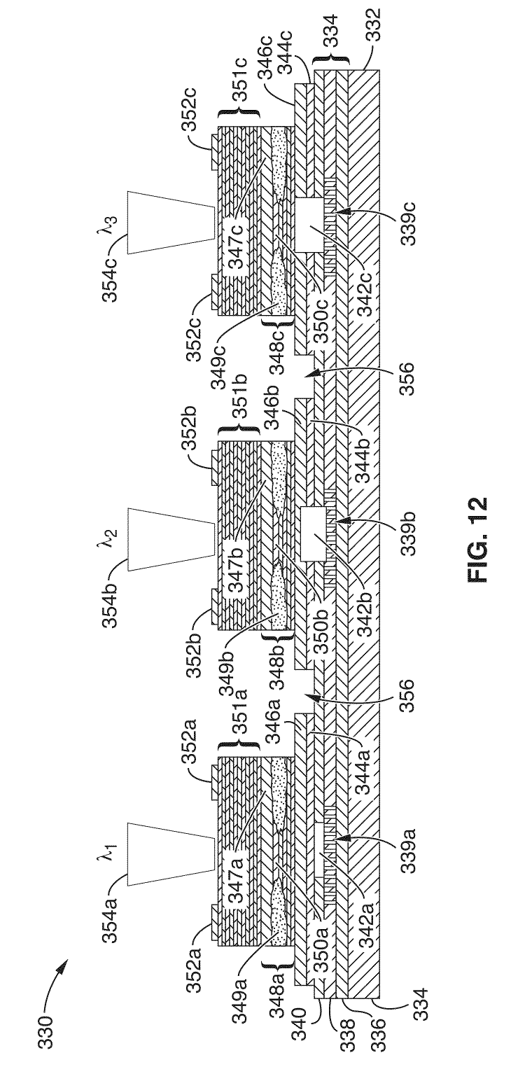

FIG. 11 and FIG. 12 show examples of an HCG patterned substrate upon which half-lasers, hereafter exemplified as half-VCSELs for the described embodiment, are connected that generate different wavelengths (λ₁, λ₂, λ₃) of light output. The examples illustrate that a multi-wavelength VCSEL array can be achieved by varying the geometries of the HCG mirror and its associated layers, exemplified as changing the lower mirror geometry in FIG. 11, or by changing cavity length through varying the thickness of the air spacer above the HCG as seen in FIG. 12. It will be appreciated that this arrangement is an array of VCSEL device elements as recited in previous embodiments in which the output wavelength of individual VCSEL devices is individually set according to readily established device parameters.

In at least one embodiment, the array of surface-emitting laser devices can be integrated on a photonics-based optical circuit that may combine other types of optical devices, such as optical ports, filters, multiplexers, demultiplexers, photodetectors and combinations thereof.

The example embodiment 290 of FIG. 11 shows a HCG patterned array substrate 292 having a silicon base layer 294, a lower spacer layer 296, and a grating layer 298 (e.g., patterned Si) with periodic spaced apart segments 299a, 299b, 299c of Si having different geometries for different individual VCSEL. A patterned metal layer 300 is formed over the grating layer 298 with air spacers 302a, 302b, 302c. It will be noted that the HCG patterned substrate may be fabricated with the metal layer or patterned metal layer, or, alternatively, this metallization and patterning step can be later performed to an HCG patterned SOI substrate prior to adding the half-VCSEL structure, or forming its layers thereupon.

Above substrate 292 is a contact layer 304a, 304b, 304c, and a current spreading and/or sacrificial layer 306a, 306b, 306c which can be sacrificial if it is also desired to extend space 302a, 302b, and 302c. An active portion 308a, 308b, 308c is seen containing active region 307a, 307b, 307c, and additional layers. The active region can optionally include additional DBR layers. The active region is shown with implanted hydrogen ions (H+) in regions 309a, 309b, 309c that form an aperture within which the lasing occurs. The active region of course contains an active layer 307a, 307b, 307c, and a current confinement layer 310a, 310b, 310c. It will be noted that the active region preferably contains any of various quantum structures, but may alternatively utilize bulk material. It should be appreciated that the order of the active layer and current confinement/optional tunnel junction layers could also be reversed. Above the active region is the top mirror structure 311a, 311b, 311c, which in this embodiment is shown comprising a series of distributed Bragg reflector (DBR) layers. A top contact 312a, 312b, 312c for the different devices which operates in combination with the common lower contact 300 for providing power to the individual VCSEL devices to generate a lasing light output 314a, 314b, and 314c at their respective wavelengths (λ₁, λ₂, λ₃).

The example embodiment 330 of FIG. 12 shows a HCG patterned array substrate 332 having a silicon base layer 334, a lower spacer layer 336, and a grating layer 338 with equivalent periodic spaced apart segments 339a, 339b, 339c. A patterned metal layer 340 is formed over the grating with equivalent air spaces 342a, 342b, 342c. Above substrate 332 is a contact layer 344a, 344b, 344c, and a sacrificial layer 346a, 346b, 346c, the combination of which has been etched to different depths to alter the output wavelengths of each of these VCSEL devices. An active portion 348a, 348b, 348c is shown as containing active regions 347a, 347b, 347c, and may contain additional DBR layers. The active region is shown with implanted hydrogen ions (H+) in regions 349a, 349b, 349c that form the aperture within which the lasing occurs. Active region 348a, 348b, 348c also preferably contains a current spreading layer 350a, 350b, 350c. It should be appreciated that the order of the active layer and current confinement/optional tunnel junction layers can be reversed without departing from the invention. Above the active region is the top mirror structure 351a, 351b, 351c, which in this embodiment is shown as comprising a series of distributed Bragg reflector (DBR) layers. A top contact 352a, 352b, 352c for the different devices which operates in combination with the common lower contact 340 for providing power to the individual VCSEL devices to generate a lasing light output 354a, 354b, and 354c at their respective wavelengths (λ₁, λ₂, λ₃).

It will be noted that in FIG. 11 the output wavelengths (frequencies) of the individual VCSELs of the integrated circuit array are established in response to changing the HCG patterning of the substrate, while each of the half-VCSEL devices on the substrate are identical. The converse is seen in FIG. 12 in which lasing wavelength is established in response to the etch depth of the contact and sacrificial layers. This allows for the reproducible manufacture of VCSEL array whose individual elements span a range of wavelength outputs, with a minimum of process step changes per device, and it has been seen that the devices are tolerant to these parameter changes because of the readily modeled and predictable characteristics of the HCG structures. It should also be appreciated that other geometries of the HCG and its adjacent layers, either separately or in combination, to individually establish lasing wavelength.

It should be appreciated that the upper mirror in FIG. 11 and FIG. 12 can be replaced by other mirrors elements, in particular the HCG upper mirror shown in FIG. 2 and FIG. 4.

From the discussion above it will be appreciated that the invention can be embodied in various ways, including the following:

1. A surface-emitting laser apparatus, comprising: a half-VCSEL laser heterostructure having an upper mirror reflector, and an active region beneath said upper mirror reflector; and a high-contrast grating (HCG) pre-patterned silicon-on-insulator (SOI) substrate comprising a buried high contrast grating disposed between spacing layers as a lower mirror reflector; wherein attaching said half-VCSEL to said HCG pre-patterned silicon-on-insulator (SOI) substrate results in a surface-emitting laser device.

2. The apparatus of embodiment 1, wherein said upper mirror reflector comprises a high contrast grating (HCG).

3. The apparatus of embodiment 1, wherein said upper mirror reflector comprises a distributed Bragg reflector (DBR).

4. The apparatus of embodiment 1, wherein said lower mirror reflector comprises Si segments forming a sub-wavelength high contrast grating (HCG).

5. The apparatus of embodiment 1, wherein said half-VCSEL structure comprises compounds selected from group III-V or II-VI compounds

6. The apparatus of embodiment 5, wherein said compounds are selected from group III-V or II-VI compounds consisting of InP-, GaAs-, GaSb-, GaN-, GaP-, ZnSSe-, ZnCdS-, ZnO2-based compound semiconductor materials and combinations thereof.

7. The apparatus of embodiment 1, further comprising one or more current spreading layers on either side of said active region within said half-VCSEL heterostructure.

8. The apparatus of embodiment 1, wherein said active region comprises quantum wells, quantum wires, quantum dots, bulk regions, or combinations thereof.

9. The apparatus of embodiment 1, wherein emission wavelength of said active region can be configured in the range from 0.1 μm to 10 μm.

10. The apparatus of embodiment 1, wherein said upper mirror reflector comprises an epitaxial DBR, dielectric DBR or HCG mirror.

11. The apparatus of embodiment 1, wherein said SOI substrate comprises Si substrate, oxide spacer and a grating layer.

12. The apparatus of embodiment 1, further comprising a spacer layer disposed over said grating layer.

13. The apparatus of embodiment 12, wherein said spacer layer comprises a material layer of low refractive index, or an etched void in a material layer.

14. The apparatus of embodiment 1: wherein said surface-emitting laser apparatus is part of an array of said surface-emitting laser devices; and wherein the geometry of said high-contrast grating (HCG) in the pre-patterned silicon-on-insulator (SOI) substrate of individual surface-emitting laser devices is adapted during fabrication to establish individual output wavelengths.

15. The apparatus of embodiment 14, further comprising an integrated optical coupler for combining laser outputs from said array of said surface-emitting laser devices.

16. The apparatus of embodiment 14, wherein said array of said surface-emitting laser device is integrated on a photonics-based optical circuit combining types of optical devices selected from the group of optical devices consisting of optical ports, filters, multiplexers, demultiplexers, and photodetectors.

17. The apparatus of embodiment 1: wherein said surface-emitting laser apparatus is part of an array of said surface-emitting laser devices; and wherein the geometry of said high-contrast grating (HCG) in the upper reflector of said half-VCSEL laser heterostructure for individual surface-emitting laser devices is adapted during fabrication to establish individual output wavelengths.

18. The apparatus of embodiment 17, further comprising an integrated optical coupler for combining laser outputs from said array of said surface-emitting laser devices.

19. The apparatus of embodiment 17, wherein said array of said surface-emitting laser device is integrated on a photonics-based optical circuit combining types of optical devices selected from the group of optical devices consisting of optical ports, filters, multiplexers, demultiplexers, and photodetectors.

20. The apparatus of embodiment 1, further comprising a contact layer disposed above said high-contrast grating (HCG) pre-patterned silicon-on-insulator (SOI) substrate.

21. The apparatus of embodiment 20: wherein said surface-emitting laser apparatus is part of an array of said surface-emitting laser devices; and wherein a contact layer is etched to a depth for individual surface-emitting laser devices to establish individual output wavelengths.

22. The apparatus of embodiment 1, further comprising implanted ions about said active region for current confinement in said surface-emitting laser apparatus.

23. The apparatus of embodiment 1, further comprising at least one sub-wavelength high-contrast grating (HCG) at or above said upper mirror reflector.

24. The apparatus of embodiment 1, wherein said apparatus is adapted for coupling to a vertical coupler having a high contrast grating interoperably coupled over a predetermined gap to a waveguide, so that light emitted from said apparatus is coupled to said waveguide.

25. The apparatus of embodiment 1, wherein said surface-emitting laser apparatus is one device in an array of surface-emitting laser devices on an integrated circuit.

26. A method of fabricating a vertical cavity surface-emitting laser apparatus, comprising: patterning a silicon-on-insulator (SOI) substrate to have a buried HCG grating as a lower reflector; fabricating a half-VCSEL heterostructure with an active region and upper reflector, said half-VCSEL heterostructure configured for attachment to said SOI substrate; and bonding said half-VCSEL heterostructure to said SOI substrate in forming a surface-emitting laser apparatus.

27. The method of embodiment 26, wherein said half-VCSEL is bonded to said pre-patterned silicon-on-insulator (SOI) substrate in response to oxide-to-oxide, or oxide-to-semiconductor bonding.

28. The method of embodiment 27, wherein said half-VCSEL is bonded to said pre-patterned silicon-on-insulator (SOI) substrate in response to thermal compressed or eutectic metal bonding.

29. The method of embodiment 26, wherein said silicon-on-insulator (SOI) substrate is configured with a plurality of buried HCG gratings as a lower reflector for receiving a plurality of half-VCSEL heterostructures within an array of vertical cavity surface-emitting lasers.

30. The method of embodiment 28, further comprising adapting the geometry of individual said buried HCG gratings as said lower reflector to change the output wavelength of individual said vertical cavity surface-emitting laser devices.

31. The method of embodiment 26, further comprising fabricating said half-VCSEL heterostructure to incorporate a contact layer and/or sacrificial layer at the boundary with said silicon-on-insulator (SOI) substrate.

32. The method of embodiment 31, wherein said silicon-on-insulator (SOI) substrate is configured with a plurality of buried HCG gratings as lower reflectors for receiving a plurality of half-VCSEL heterostructures within an array of vertical cavity surface-emitting lasers.

33. The method of embodiment 32, further comprising selectively altering said contact layer and/or sacrificial layer to change optical cavity length above said buried HCG reflectors to change the output wavelength of individual said vertical cavity surface-emitting laser devices.

34. The method of embodiment 26, further comprising top and/or backside ion implantation about said active region to confine current.

35. The method of embodiment 26, further comprising fabricating at least one sub-wavelength high-contrast grating lens on the output of said vertical cavity surface-emitting laser apparatus.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed under the provisions of 35 B.SC. 112, sixth paragraph, unless the element is expressly recited using the phrase “means for.”

What is claimed is:

1. A surface-emitting laser apparatus, comprising:
a half-VCSEL laser heterostructure having an upper mirror reflector, and an active region beneath said upper mirror reflector; and
a high-contrast grating (HCG) pre-patterned silicon-on-insulator (SOI) substrate comprising a buried high contrast grating disposed between spacing layers as a lower mirror reflector;
wherein attaching said half-VCSEL to said HCG pre-patterned silicon-on-insulator (SOI) substrate results in a surface-emitting laser device.

2. The apparatus recited in claim 1, wherein said upper mirror reflector comprises a high contrast grating (HCG).

3. The apparatus recited in claim 1, wherein said upper mirror reflector comprises a distributed Bragg reflector (DBR).

4. The apparatus recited in claim 1, wherein said lower mirror reflector comprises Si segments forming a sub-wavelength high contrast grating (HCG).

5. The apparatus recited in claim 1, wherein said half-VCSEL structure comprises compounds selected from group III-V or II-VI compounds

6. The apparatus recited in claim 5, wherein said compounds are selected from group III-V or II-VI compounds consisting of InP-, GaAs-, GaSb-, GaN-, GaP-, ZnSSe-, ZnCdS-, ZnO2-based compound semiconductor materials and combinations thereof.

7. The apparatus recited in claim 1, further comprising one or more current spreading layers on either side of said active region within said half-VCSEL heterostructure.

8. The apparatus recited in claim 1, wherein said active region comprises quantum wells, quantum wires, quantum dots, bulk regions, or combinations thereof.

9. The apparatus recited in claim 1, wherein emission wavelength of said active region can be configured in the range from 0.1 μm to 10 μm.

10. The apparatus recited in claim 1, wherein said upper mirror reflector comprises an epitaxial DBR, dielectric DBR or HCG mirror.

11. The apparatus recited in claim 1, wherein said SOI substrate comprises Si substrate, oxide spacer and a grating layer.

12. The apparatus recited in claim 1, further comprising a spacer layer disposed over said grating layer.

13. The apparatus recited in claim 12, wherein said spacer layer comprises a material layer of low refractive index, or an etched void in a material layer.

14. The apparatus recited in claim 1:
wherein said surface-emitting laser apparatus is part of an array of said surface-emitting laser devices; and
wherein the geometry of said high-contrast grating (HCG) in the pre-patterned silicon-on-insulator (SOI) substrate of individual surface-emitting laser devices is adapted during fabrication to establish individual output wavelengths.

15. The apparatus recited in claim 14, further comprising an integrated optical coupler for combining laser outputs from said array of said surface-emitting laser devices.

16. The apparatus recited in claim 14, wherein said array of said surface-emitting laser device is integrated on a photonics-based optical circuit combining types of optical devices selected from the group of optical devices consisting of optical ports, filters, multiplexers, demultiplexers, and photodetectors.

17. The apparatus recited in claim 1:
wherein said surface-emitting laser apparatus is part of an array of said surface-emitting laser devices; and
wherein the geometry of said high-contrast grating (HCG) in the upper reflector of said half-VCSEL laser heterostructure for individual surface-emitting laser devices is adapted during fabrication to establish individual output wavelengths.

18. The apparatus recited in claim 17, further comprising an integrated optical coupler for combining laser outputs from said array of said surface-emitting laser devices.

19. The apparatus recited in claim 17, wherein said array of said surface-emitting laser device is integrated on a photonics-based optical circuit combining types of optical devices selected from the group of optical devices consisting of optical ports, filters, multiplexers, demultiplexers, and photodetectors.

20. The apparatus recited in claim 1, further comprising a contact layer disposed above said high-contrast grating (HCG) pre-patterned silicon-on-insulator (SOI) substrate.

21. The apparatus recited in claim 20:
wherein said surface-emitting laser apparatus is part of an array of said surface-emitting laser devices; and
wherein a contact layer is etched to a depth for individual surface-emitting laser devices to establish individual output wavelengths.

22. The apparatus recited in claim 1, further comprising implanted ions about said active region for current confinement in said surface-emitting laser apparatus.

23. The apparatus recited in claim 1, further comprising at least one sub-wavelength high-contrast grating (HCG) at or above said upper mirror reflector.

24. The apparatus recited in claim 1, wherein said apparatus is adapted for coupling to a vertical coupler having a high contrast grating interoperably coupled over a predetermined gap to a waveguide, so that light emitted from said apparatus is coupled to said waveguide.

25. The apparatus recited in claim 1, wherein said surface-emitting laser apparatus is one device in an array of surface-emitting laser devices on an integrated circuit.

26. A method of fabricating a vertical cavity surface-emitting laser apparatus, comprising:
patterning a silicon-on-insulator (SOI) substrate to have a buried HCG grating as a lower reflector;
fabricating a half-VCSEL heterostructure with an active region and upper reflector, said half-VCSEL heterostructure configured for attachment to said SOI substrate; and
bonding said half-VCSEL heterostructure to said SOI substrate in forming a surface-emitting laser apparatus.

27. The method recited in claim 26, wherein said half-VCSEL is bonded to said pre-patterned silicon-on-insulator (SOI) substrate in response to oxide-to-oxide, or oxide-to-semiconductor bonding.

28. The method recited in claim 27, wherein said half-VCSEL is bonded to said pre-patterned silicon-on-insulator (SOI) substrate in response to thermal compressed or eutectic metal bonding.

29. The method recited in claim 26, wherein said silicon-on-insulator (SOI) substrate is configured with a plurality of buried HCG gratings as a lower reflector for receiving a plurality of half-VCSEL heterostructures within an array of vertical cavity surface-emitting lasers.

30. The method recited in claim 28, further comprising adapting the geometry of individual said buried HCG gratings as said lower reflector to change the output wavelength of individual said vertical cavity surface-emitting laser devices.

31. The method recited in claim 26, further comprising fabricating said half-VCSEL heterostructure to incorporate a contact layer and/or sacrificial layer at the boundary with said silicon-on-insulator (SOI) substrate.

32. The method recited in claim 31, wherein said silicon-on-insulator (SOI) substrate is configured with a plurality of buried HCG gratings as lower reflectors for receiving a plurality of half-VCSEL heterostructures within an array of vertical cavity surface-emitting lasers.

33. The method recited in claim 32, further comprising selectively altering said contact layer and/or sacrificial layer to change optical cavity length above said buried HCG reflectors to change the output wavelength of individual said vertical cavity surface-emitting laser devices.

34. The method recited in claim 26, further comprising top and/or backside ion implantation about said active region to confine current.

35. The method recited in claim 26, further comprising fabricating at least one sub-wavelength high-contrast grating lens on the output of said vertical cavity surface-emitting laser apparatus.
